(19) United States
(12) Patent Application Publication
(10) Pub. No.: US 2017/0031118 A1
(43) Pub. Date: Feb. 2, 2017

(54) OPTOELECTRONIC COMPONENTS HOUSED IN A TO-CAN PACKAGE

(71) Applicant: Avago Technologies General IP (Singapore) Pte. Ltd., Singapore (SG)

(72) Inventors: Ayman Kanan, Allentown, PA (US); Kou-Wei Wang, Orefield, PA (US); Nicholas Jordache, Fleetwood, PA (US)

(21) Appl. No.: 14/815,423

(22) Filed: Jul. 31, 2015

(51) Int. Cl. G02B 6/42; H01S 5/026; H01S 5/022; G02B 6/32

(52) U.S. Cl. CPC G02B 6/4263; G02B 6/325; G02B 6/4214; G02B 6/4257; G02B 6/4206; G02B 6/4286; H01S 5/0264; H01S 5/02212

(57) ABSTRACT

Various types of optoelectronic components are housed inside a standard TO-can package. In a first exemplary embodiment, a sub-assembly is mounted on a substrate of a TO-can package such that a major surface of the sub-assembly is oriented orthogonal to a major surface of the substrate. The sub-assembly includes a light emitter and a light directing element that is arranged at a fixed distance from the light emitter prior to mounting of the sub-assembly on the substrate. The fixed distance is based on a first mounted distance formed between the light directing element and an optical window of the TO-can package when the sub-assembly is mounted on the substrate. In a second exemplary embodiment, a planar lightwave circuit incorporating an optical waveguide combiner, is mounted on the substrate of a TO-can package. The planar lightwave circuit includes two light emitters emitting light at different wavelengths into the optical waveguide combiner.

### FIELD OF THE INVENTION

The invention relates to packaging, and more particularly, to packaging of optoelectronic components in a TO-can package.

### BACKGROUND

Various types of optoelectronic components are known in the art. Such optoelectronic components can include, for example, optical emitters that generate optical signals, photodetectors that detect optical signals, driver devices that provide electrical signals for driving optical emitters, monitor devices that are used for monitoring optical signals, and signal converters that convert signals from the electrical domain to the optical domain and vice-versa. These optoelectronic components are generally made available in a variety of packages, some of which are uniquely customized on the basis of factors such as size, cost, application, and packaging density.

The term “packaging density” generally refers to the number of discrete components that can be housed inside a single package. In some cases, the packaging density is primarily geared towards maximizing the number of discrete optoelectronic components that can be housed inside a single package. This can be carried out by miniaturizing and replicating certain types of optoelectronic components, such as, for example, a light emitting diode (LED). However, while it may be relatively easy to combine a large number of LEDs inside a single package, it can be more difficult to package a large number of some other types of optoelectronics devices, such as, for example, certain types of laser emitters. As is known, a laser emitter requires precise optical focusing and a controlled operating environment for proper functioning. Consequently, combining two or more laser emitters inside a single package can pose several challenges both in terms of feasibility and performance.

Among these various challenges, one pertains to providing a package that not only provides satisfactory device performance but also meets various industry-wide packaging standards. As is known, during a large scale manufacture of an optoelectronic product, an automated handling system may be used for installing one or more components upon a base element, such as a printed circuit board, that is contained inside the optoelectronic product. Such automated handling systems are typically designed to handle packages that satisfy industry-wide packaging standards. Thus, re-tooling these automated handling systems to handle non-standard packages can be expensive and inefficient. It is therefore desirable to use a standardized package when attempting to increase packaging density of various types of optoelectronic devices.

### BRIEF DESCRIPTION OF THE FIGURES

Many aspects of the invention can be better understood by referring to the following description in conjunction with the accompanying claims and figures. Like numerals indicate like structural elements and features in the various figures. For clarity, not every element may be labeled with numerals in every figure. The drawings are not necessarily drawn to scale, emphasis instead being placed upon illustrating the principles of the invention. The drawings should not be interpreted as limiting the scope of the invention to the example embodiments shown herein.

FIG. 1 shows a first exemplary embodiment of a light emitting device in the form of a TO-can package housing a pre-assembled optoelectronic package, the pre-assembled package including a light emitting element and a primary collimating optical element.

FIG. 2 shows a second exemplary embodiment of a light emitting device in the form of a TO-can package housing a pre-assembled optoelectronic package, the pre-assembled package including a pair of light emitting elements and a corresponding pair of primary focusing optical elements.

FIG. 3 shows a third exemplary embodiment of a light emitting device in the form of a TO-can package having a first set of optoelectronic devices mounted on a substrate of the TO-can package.

FIG. 4 shows a fourth exemplary embodiment of a light emitting device in the form of a TO-can package having a second set of optoelectronic devices mounted on a substrate of the TO-can package.

FIG. 5 shows an exemplary optical system that includes a controller communicatively coupled to the light emitting device shown in FIG. 4.

FIG. 6 shows a fifth exemplary embodiment of a light emitting device in the form of a TO-can package housing a planar lightwave circuit, the planar lightwave circuit including a third set of optoelectronic devices mounted on a sub-assembly.

FIG. 7 shows a sixth exemplary embodiment of a light emitting device in the form of a TO-can package housing a planar lightwave circuit, the planar lightwave circuit including a fourth set of optoelectronic devices mounted on a sub-assembly.

FIG. 8 shows an exemplary optical system that includes a controller communicatively coupled to the light emitting device shown in FIG. 7.

FIG. 9 shows a seventh exemplary embodiment of a light emitting device in the form of a TO-can package housing a planar lightwave circuit in an alternative mounting arrangement to that shown in FIG. 6.

### WRITTEN DESCRIPTION

Throughout this description, embodiments and variations are described for the purpose of illustrating uses and implementations of inventive concepts. The illustrative description should be understood as presenting examples of inventive concepts, rather than as limiting the scope of the concepts as disclosed herein. It should be further understood that certain words and terms are used herein solely for convenience and such words and terms should be interpreted as referring to various objects and actions that are generally understood in various forms and equivalencies by persons of ordinary skill in the art. For example, the word “optoelectronic” as used herein encompasses various types of optical components and electrical components that can be used in various types of circuits that have at least one portion incorporating light propagation; the words “connected” or “coupled” generally refer to two elements that have electrical connectivity via a metal track or a wire for example, and the word “line” as used herein generally refers to a metal track or a wire connection for example. Some non-limiting examples of optical components can include a lens, a prism, and a mirror, while some examples of electrical components that can be used in association with optical components include a driver, a monitor, an electrical-to-optical converter, and an optical-to-electrical converter. It should also be understood that the word “example” as used herein is intended to be non-exclusionary and non-limiting in nature. More particularly, the word “exemplary” as used herein indicates one among several examples, and it must be understood that no undue emphasis or preference is being directed to the particular example being described.

Generally, in accordance with the various illustrative embodiments disclosed herein, various types of optoelectronic components are housed inside a standard TO-can package. TO-can packages are well known in the industry and provide various advantages in terms of manufacture and use. The various types of optoelectronic components housed in a TO-can package as disclosed herein, provide various advantages in terms of capabilities, configurations, manufacturability, and performance.

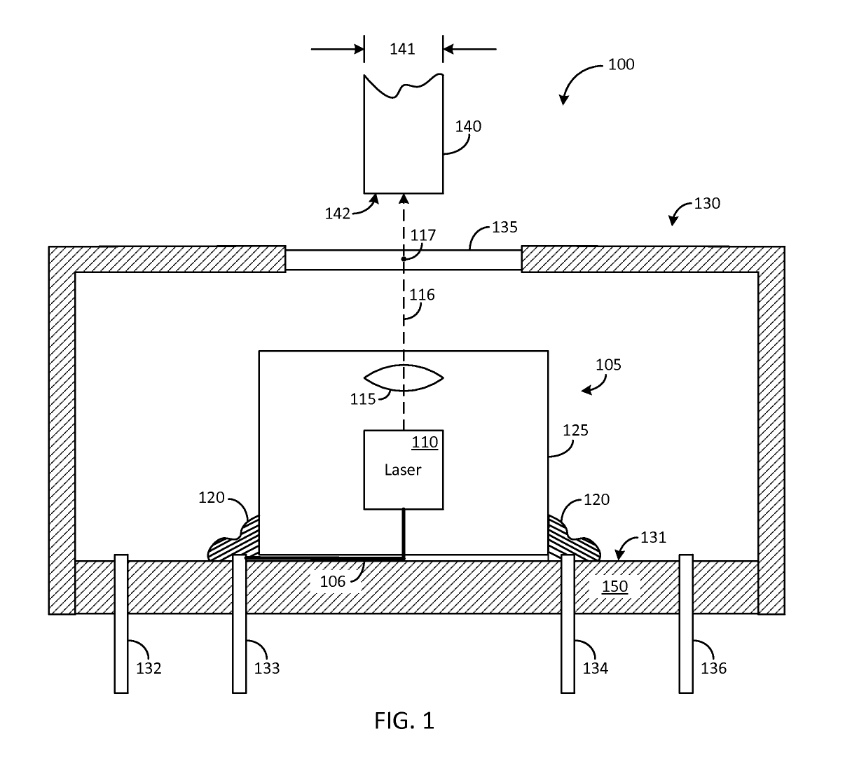

Attention is now drawn to FIG. 1, which shows a first exemplary embodiment of a light emitting device 100 that includes a TO-can package 130 inside which is housed a sub-assembly 105, in accordance with the disclosure. The sub-assembly 105 is provided in the form of a platform 125 on which various optoelectronic components are mounted. The platform 125 can be, for example, a printed circuit board (PCB), a ceramic substrate, a glass substrate, or an alumina substrate.

In this first exemplary embodiment, a light emitting element in the form of a laser 110, and a primary collimating optical element in the form of a lens 115, are mounted on the platform 125. The laser 110, which can be one of various types of devices, such as, for example, a vertical cavity surface emitting laser (VCSEL) or an edge-emitting laser, is coupled via one or metal tracks to one or more pins of the TO-can package 130. One such exemplary metal track 106 is shown connecting the laser 110 to a pin 133. Additional pins, such as the pins 132, 134 and 136 can be used for other connections to the sub-assembly 105 or to other elements (not shown) housed inside the TO-can package 130. It should be understood, that the pin 133 and other such pins 132, 134, and 136 that are shown in FIG. 1 (as well as in other figures) in the form of pins, are merely illustrative in nature and in various implementations, other connecting elements, such as solder balls, tabs, or surface mount leads can be used for providing external connectivity to the TO-can package 130.

The sub-assembly 105 can be mounted upon a substrate 150 of the TO-can package 130 in a variety of ways. For example, a suitable adhesive or mounting compound 120 can be used for this purpose. Particular notice is drawn to the orientation and placement of the sub-assembly 105 upon the substrate 150. Specifically, in this exemplary embodiment, a major surface of the sub-assembly 105 is oriented orthogonal to a top major surface 131 of the substrate 150. Furthermore, the sub-assembly 105 is mounted on the substrate 150 at a pre-designated location that is defined at least in part, by an optical alignment of a principal axis 116 of the lens 115 with an optical center 117 of an optical window 135 that constitutes a light emitting surface of the TO-can package 130.

When in operation, the laser 110 emits light that is propagated through the lens 115 and directed towards the optical window 135. In a first example implementation, the optical window 135 is a transparent planar element such as, for example, a glass pane, through which light received from the lens 115 is propagated to an optical fiber 140. In this first example implementation, the lens 115 is a focusing lens that focuses the emitted light upon a receiving end of the optical fiber 140.

In a second example implementation, the optical window 135 is configured as a collimating lens rather than as a transparent planar element, and the lens 115 is a collimating lens. The lens 115 operates as a primary collimating optical element and the optical window 135 operates as an additional collimating optical element when propagating the emitted light to a receiving end 142 the optical fiber 140. The additional collimation provided by the optical window 135 can be tailored for example, in accordance with a core diameter 141 of the optical fiber 140 (cladding not shown).

In a third example implementation, the optical window 135 is configured as a focusing lens that receives light from the lens 115, which is operative as either a primary focusing optical element or a primary collimating optical element, and focusses the light upon the receiving end 142 of the optical fiber 140.

The sub-assembly 105 offers various advantages such as, for example, permitting the lens 115 to be mounted on the platform 125 at a fixed distance from the laser 110. The fixed distance, which can be predetermined prior to manufacture, provides for a fixed focus arrangement between the lens 115 and the laser 110 and can eliminate one or more manual optical alignment procedures during product manufacture or later. Furthermore, reduced manufacturing costs and improved product yield can be achieved as a result of carrying out various operations such as, for example, quality control operations, upon the sub-assembly 105, prior to placing it inside the TO-can package 130 during manufacture.

More particularly, upon placing the sub-assembly 105 on the substrate 150, the lens 115 and the optical window 135 are automatically aligned and/or focused due to the resulting mounted distance between the lens 115 and the optical window 135. The mounted distance can be used for determining a placement of the lens 115 on the sub-assembly 105 during manufacture of the sub-assembly 105 and prior to mounting upon the substrate 150.

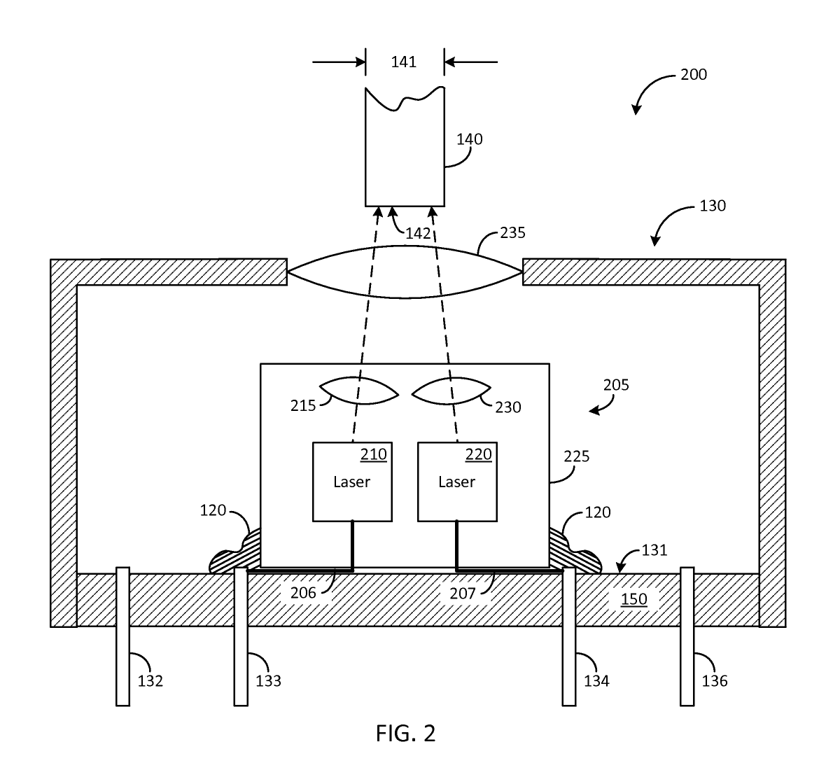

FIG. 2 shows a second exemplary embodiment of a light emitting device 200 that includes the TO-can package 130 inside which is housed a sub-assembly 205, in accordance with the disclosure. The sub-assembly 205 can include various optoelectronic components that are mounted on a platform 225. The platform 225 can be, for example, a printed circuit board (PCB), a ceramic substrate, a glass substrate, or an alumina substrate. In this second exemplary embodiment, two light emitting elements (in the form of a first laser 210 and a second laser 220) and two corresponding primary focusing optical elements (in the form of a first lens 215 and a second lens 230) are mounted on the platform 225.

The first laser 210 and the second laser 220 can be one of various types of devices, such as, for example, a vertical cavity surface emitting laser (VCSEL) or an edge-emitting laser. The first laser 210 is coupled via a first metal track 206 to the pin 133 and the second laser 220 is coupled via a second metal track 207 to the pin 134. Pins 132 and 136 can be used for other connections to the sub-assembly 205 or to other elements (not shown) housed inside the TO-can package 130.

The sub-assembly 205 can be mounted upon a substrate 150 of the TO-can package 130 in a variety of ways. For example, a suitable adhesive or mounting compound 120 can be used for this purpose. Particular attention is drawn to the orientation and placement of the sub-assembly 205 upon the substrate 150. Specifically, a major surface of the sub-assembly 205 is oriented orthogonal to a top major surface 131 of the substrate 150. Furthermore, the sub-assembly 205 is mounted on the substrate 150 at a predesignated location that is defined at least in part, by a predetermined optical alignment of each of the first lens 215 and the second lens 230 with respect to a focusing lens 235 that constitutes a light emitting surface of the TO-can package 130.

The first lens 215 is mounted on the platform 225 in a manner that not only enables a fixed focus relationship with respect to the laser 210 but also provides a primary focusing action upon light emitted by the laser 210 when directing this emitted light towards the focusing lens 235. The second lens 230 is mounted on the platform 225 in a manner that not only enables a fixed focus relationship with respect to the laser 220 but also provides a primary focusing action upon light emitted by the laser 220 when directing this emitted light towards the focusing lens 235.

The combination of the primary focusing action provided by each of the first lens 215 and the second lens 220 and the secondary focusing action provided by the focusing lens 235 results in a converged beam of light that is incident upon the light receiving portion 142 of the optical fiber 140. The sub-assembly 205 offers various advantages similar to those described above with respect to the sub-assembly 105.

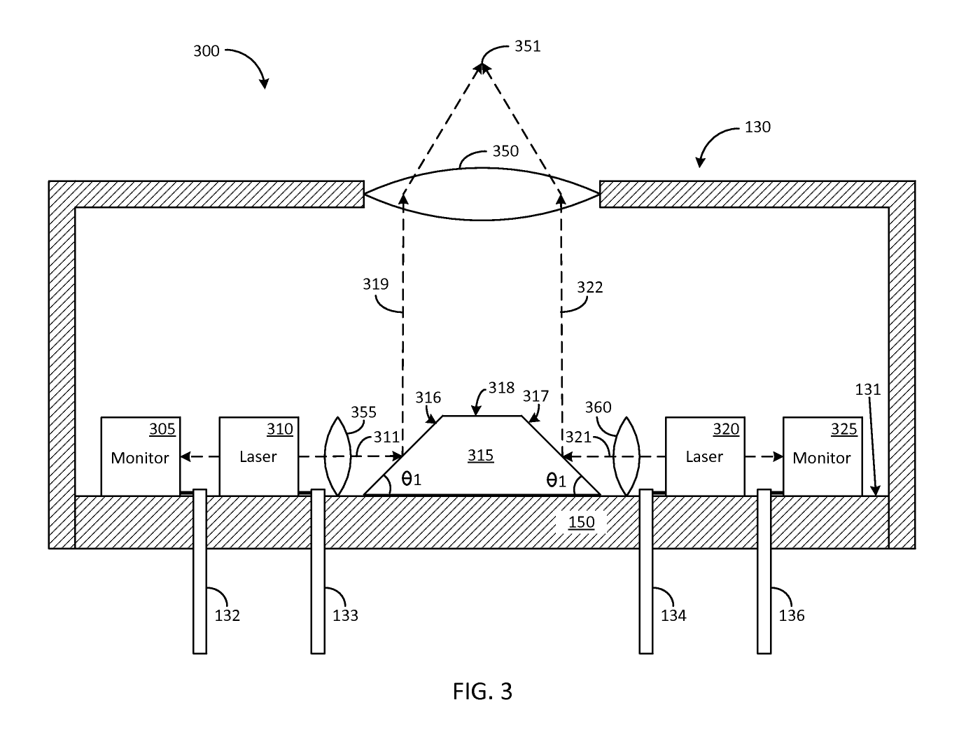

FIG. 3 shows a third exemplary embodiment of light emitting device 300 in the form of the TO-can package 130 housing a first set of optoelectronic devices mounted directly on the substrate 150 of the TO-can package 130. The first set of optoelectronic devices include a first laser 310, a second laser 320, a first monitor 305, a second monitor 325, a first lens 355, and a second lens 360, and a light directing element 315. One or all of the first monitor 305, the second monitor 325, the first lens 355, and the second lens 360 can be omitted in some implementations where the functionality provided by these optoelectronic elements are deemed optional.

The first laser 310 is arranged such that a first light emitting axis 311 of the first laser 310 is substantially parallel to the top major surface 131 of the substrate 150 and directed towards a first light reflecting surface 316 of the light directing element 315. The first lens 355 can be interposed between the first laser 310 and the first light reflecting surface 316 in some implementations. The second laser 320 is arranged such that a second light emitting axis 321 of the second laser 320 is substantially parallel to the top major surface 131 the substrate 150 and directed towards a second light reflecting surface 317 of the light directing element 315. The second lens 360 can be interposed between the second laser 320 and the second light reflecting surface 317 in some implementations. Each of the first light reflecting surface 316 and the second light reflecting surface 317 can be fabricated in several alternative ways, for example, by gold-plating an obverse side and a reverse side of the light directing element 315.

In this exemplary embodiment, the first light emitting axis 311 is oriented in a directly opposing direction to the second light emitting axis 321. However, in other embodiments, the first light emitting axis 311 can be oriented at various angles with respect to the second light emitting axis 321 and each of the first light reflecting surface 316 and the second light reflecting surface 317 of the light directing element 315 arranged accordingly.

Furthermore, in this exemplary embodiment, the light directing element 315 is provided in the form of a mesa shaped pyramidal component having a flat-top mesa portion 318 and at least two reflecting surfaces (i.e., the first light reflecting surface 316 and the second light reflecting surface 317) that face away from each other and configured to receive light propagating in opposite directions to each other. Specifically, each of the first light reflecting surface 316 and the second light reflecting surface 317 is oriented at a 45 degree angle (“θ1”) with respect to the top major surface 131 of the substrate 150. As a result of the 45 degree angle orientation, light received from the first laser 310 that is incident upon the first light reflecting surface 316 is reflected orthogonally upwards along the light propagating path 319 towards a focusing lens 350. Similarly, light received from the second laser 320 that is incident upon the second light reflecting surface 317 is reflected orthogonally along the light propagating path 322 towards the focusing lens 350. The focusing lens 350, which constitutes a light emitting surface of the TO-can package 130, provides convergence of the light emitted by each of the first laser 310 and the second laser 320 to a focal point 351. In an alternative implementation, the flat-top mesa portion 318 of the light directing element 315 can be eliminated and the light directing element 315 can constitute a true pyramid.

Various characteristics of the light emitted by the first laser 310 can be monitored by using the first monitor 305. The first monitor 305 receives light emitted from a rear facet of the first laser 310 and converts the received light into one or more electrical signals that are coupled into the pin 132 of the TO-can package 130. The one or more electrical signals generated by the first monitor 305 provide information such as, for example, an amplitude of the light emitted by the first laser 310 towards the light directing element 315, or a wavelength of the light emitted by the first laser 310 towards the light directing element 315.

The operation of the second monitor 325 vis-à-vis the second laser 320 is similar to that described above with respect to the first monitor 305. The one or more electrical signals generated by the second monitor 325 are coupled into the pin 136 of the TO-can package 130.

The light emitting device 300 can be configured and used in various ways. In a first exemplary implementation, each of the first laser 310 and the second laser 320 is configured to emit light at a first wavelength. Consequently, an amplitude of light arriving at the focal point 351 at the first wavelength, is a sum of a first amplitude of light emitted by the first laser 310 and a second amplitude of light emitted by the second laser 320. The first amplitude of light emitted by the first laser 310 can be set equal to, or different than, the second amplitude of light emitted by the second laser 310.

In a second exemplary implementation, the first laser 310 is configured to emit light at a first wavelength and the second laser 320 is configured to emit light at a second wavelength. Consequently, light arriving at the focal point 351 is wavelength multiplexed light containing a combination of the light at the first wavelength and the light at the second wavelength. The amplitude of light at the first wavelength can be set equal to, or different than, the amplitude of light at the second wavelength.

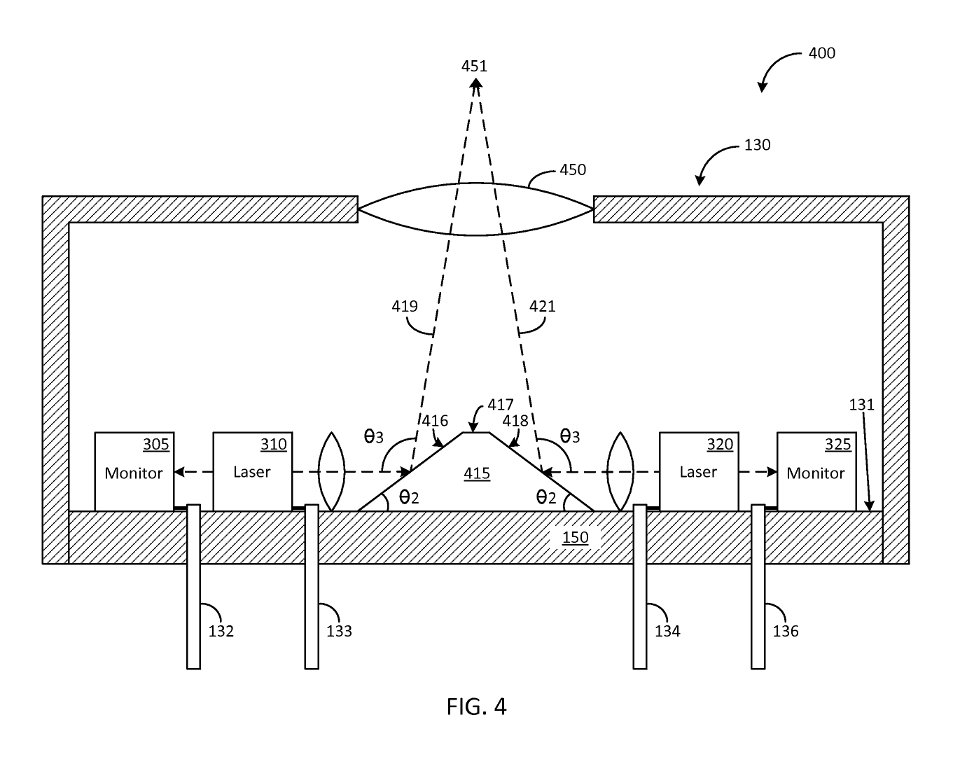

Attention is next drawn to FIG. 4, which shows a fourth exemplary embodiment of a light emitting device 400 in the form of the TO-can package 130 housing a second set of optoelectronic devices mounted on the substrate 150 of the TO-can package 130. The second set of optoelectronic devices is similar to the first set of optoelectronic devices described above with respect to the light emitting device 300, except for certain differences between the light directing element 315 of the light emitting device 300 and the light directing element 415 of the light emitting device 400.

Specifically, the light directing element 315 of the light emitting device 300 has each of the first light reflecting surface 316 and the second light reflecting surface 317 oriented at a 45 degree angle (“θ1”) with respect to the top major surface 131 of the substrate 150. In contrast, the light directing element 415 of the light emitting device 400 has each of a first light reflecting surface 416 and a second light reflecting surface 418 oriented at an angle (“θ2”) that is less than 45 degrees with respect to the top major surface 131 of the substrate 150.

As a result of the less than 45 degree angle orientation, light received from the first laser 310 that is incident upon the first light reflecting surface 416 is reflected towards the focusing lens 450 along the light propagating path 419 at an angle (“θ3”) greater than 90 degrees. Similarly, light received from the second laser 320 that is incident upon the second light reflecting surface 417 is reflected along the light propagating path 421 towards the focusing lens 450 at the angle (“θ3”) that is greater than 90 degrees. The focusing lens 450 provides convergence of the light received along each of the light propagating path 419 and the light propagating path 421 to a focal point 451 that can be different from the focal point 351 shown in FIG. 3.

As a further result of the less than 45 degree angle orientation (“θ2”), a flat-top mesa portion 417 of the light directing element 415 is smaller than the flat-top mesa portion 318 of the light directing element 315. In an alternative implementation, the flat-top mesa portion 417 can be eliminated and the light directing element 415 constitute a true pyramid.

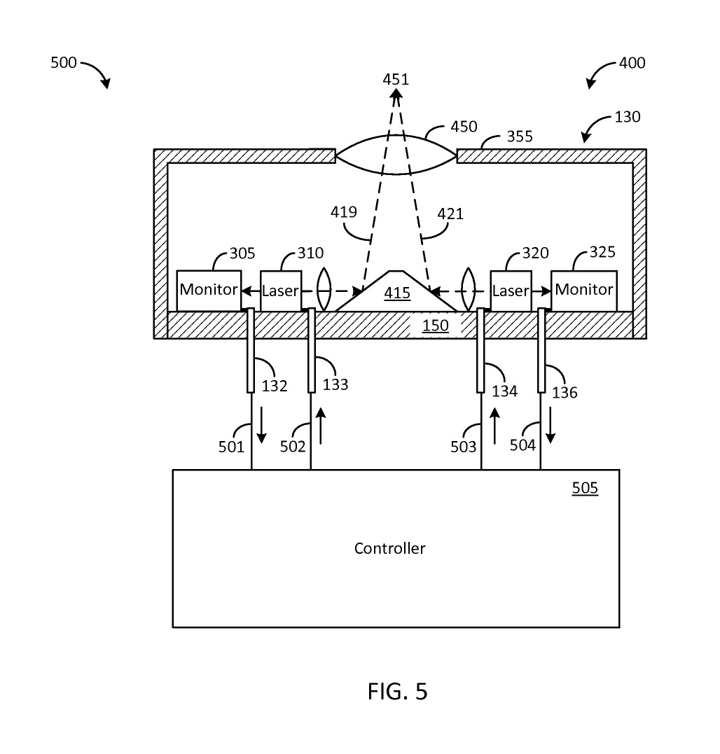

FIG. 5 shows an exemplary optical system 500 that includes a controller 505 communicatively coupled to the light emitting device 400 described above. It should be understood that the light emitting device 400 is used herein primarily as a matter of convenience for describing the optical system 500. Thus, in other exemplary embodiments, the light emitting device 400 can be replaced with various other light emitting devices such as those disclosed herein, including the light emitting device 100 and the light emitting device 200, each of which can be suitably adapted to embody the principles described herein with respect to the optical system 500.

When in operation, the first monitor 305 converts light received from the first laser 310 into a first electrical signal that is provided to the controller 505 via pin 132 of the TO-can package 130 and a link 501 that couples the pin 132 to the controller 505. Similarly, the second monitor 310 converts light received from the second laser 320 into a second electrical signal that is provided to the controller 505 via the pin 136 of the TO-can package 130 and another link 504. The controller 505 processes one or both of the first electrical signal and the second electrical signal and generates a first control signal and/or a second control signal. The first control signal is coupled into the first laser 310 via a line 502 and the pin 133 of the TO-can package 130. The second control signal is coupled into the second laser 320 via a line 503 and the pin 134 of the TO-can package 130.

The optical system 500 can be configured and used to execute a number of different operations. For example, in a first implementation, the controller 505 is configured to evaluate the first electrical signal provided by the first monitor 305 and determine a suitable course of action. For example, based on the evaluation, the controller 505 may determine that an amplitude of light emitted by the first laser 310 is improper or that the first laser 310 has suffered a malfunction. Based on this determination, the controller 505 can set the first control signal to a suitable voltage that is provided to the first laser 310 for modifying the amplitude of light emitted by the first laser 310 (or for shutting down the first laser 310). This operation performed by the controller 505 can be carried out independent of any action that is carried out by the controller 505 upon the second laser 320.

In a second exemplary implementation, the controller 505 is configured to evaluate the second electrical signal provided by the second monitor 325 and determine an operating characteristic of the first laser 310. For example, the controller 505 may determine that an amplitude of light emitted by the second laser 320 is improper or that the second laser 320 has suffered a malfunction. Based on this determination, the controller 505 can set the second control signal to a suitable voltage that is provided to the second laser 320 for modifying the amplitude of light emitted by the second laser 320 (or for shutting down the second laser 320). This operation performed by the controller 505 can be carried out independent of any control action that is carried out by the controller 505 upon the first laser 310.

In a third exemplary implementation, the controller 505 evaluates both the first electrical signal provided by the first monitor 305 and the second electrical signal provided by the second monitor 325 and determines that an amplitude of light emitted by say, the second laser 320 is improper in comparison with an amplitude of light emitted by the first laser 310. Based on this determination, the controller 505 sets the first control signal to a suitable voltage that is then provided to the first laser 310 for modifying the amplitude of light emitted by the first laser 310. In this manner, the controller 505 can set the amplitude of light emitted by the first laser 310 to be equal to the amplitude of light emitted by the second laser 320, or can set the amplitude of light emitted by the first laser 310 to be at a predetermined ratio with respect to the amplitude of light emitted by the second laser 320 (for example, the predetermined ratio can be 1:2, 1:3, 2:1, etc.)

In other alternative embodiments, the controller 505 can be configured to provide control signals that set operating characteristics other than the amplitude, such as, for example, individual wavelength, individual phase, or relative phase of one or both of the first laser 310 and the second laser 320 based on one or both of the first electrical signal provided by the first monitor 305 and the second electrical signal provided by the second monitor 325.

For example, the controller 505 can evaluate both the first electrical signal provided by the first monitor 305 and the second electrical signal provided by the second monitor 325 and set the first control signal to a suitable voltage that changes a first wavelength of light generated by the first laser 310. In this manner, the controller 505 can set the wavelength of light emitted by the first laser 310 to be identical to, or different than the wavelength of light emitted by the second laser 320. Such a wavelength adjustment may be used, for example, to compensate for aging effects, temperature-related effects, and various operating conditions.

As another example, the controller 505 is configured to disregard each of the first electrical signal provided by the first monitor 305 and the second electrical signal provided by the second monitor 325. Instead, the controller 505 can set each of the first control signal and the second control signal to alternatively enable the first laser 310 and the second laser 320. As a result, a wavelength multiplexing operation is executed wherein the first beam of light at the first wavelength propagates along the light propagating path 419 during a first instant in time and a second beam of light at the second wavelength propagates along the light propagating path 421 during a second instant in time. The resulting wavelength multiplexed signal formed at the focal point 451 can be directed into an optical fiber or other optical element.

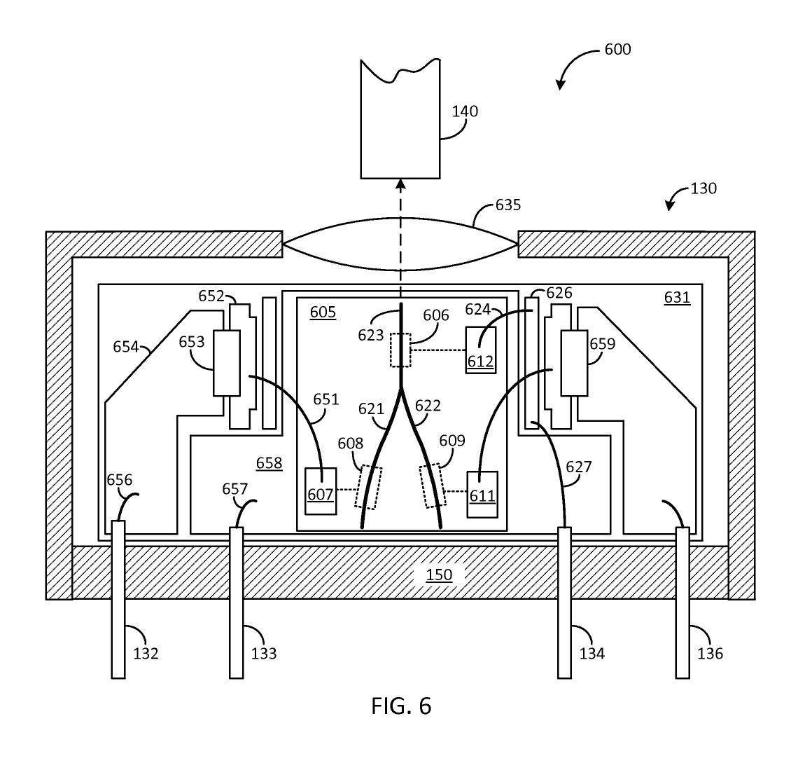

FIG. 6 shows a fifth exemplary embodiment of light emitting device 600 in the form of the TO-can package 130 housing a planar lightwave circuit 631 that includes a third set of optoelectronic devices provided on a sub-assembly 605. In one exemplary implementation, one or more of the third set of optoelectronic devices can be embedded in one or more internal layers of the sub-assembly 605 when the sub-assembly 605 is a multilayer structure. On the other hand, in another exemplary implementation, one or more of the optoelectronic devices can be mounted upon a surface of the sub-assembly 605 when either the sub-assembly 605 does not have internal layers or when it is undesirable to use an internal layer of the sub-assembly 605.

In the exemplary light emitting device 600, the sub-assembly 605 is a planar lightwave circuit incorporating an optical waveguide circuit. The sub-assembly 605 can be mounted on a ground plane layer 658 of the planar lightwave circuit 631 such that a ground plane layer (not shown) of the sub-assembly 605 is electrically coupled via a bonding wire 657 to the pin 133 of the TO-can package 130. The pin 133 can be connected to ground potential via external circuitry (not shown).

The planar lightwave circuit 631 can be mounted upon the substrate 150 of the TO-can package 130 in a variety of ways, such as for example, using a suitable adhesive or mounting compound as described above with respect to the embodiment shown in FIG. 2. Particular attention is drawn to the orientation and placement of the planar lightwave circuit 631 upon the substrate 150. Specifically, a major surface of the planar lightwave circuit 631 is oriented orthogonal to a top major surface 131 of the substrate 150.

The sub-assembly 605 includes three optical waveguides that are interconnected to each other in a Y-configuration. Specifically, the three optical waveguides constitute an optical waveguide combiner circuit that includes a first leg 621, a second leg 622, and a third leg 623. The third leg 623 propagates a combination of light received from each of the first leg 621 and the second leg 622.

Thus, when light of a first wavelength is propagated through the first leg 621 and light of a second wavelength is propagated through the second leg 622, the light propagating through the third leg 623 is wavelength multiplexed light containing both the first wavelength and the second wavelength. The light propagating through the third leg 623 is emitted out of the TO-can package 130 via a focusing lens 635 towards the optical fiber 140.

Accordingly, a first laser device 608 is arranged to emit into the first leg 621, light at the first wavelength. A second laser device 609 is arranged to emit into the second leg 621, light at the second wavelength. Each of the first laser device 608 and the second laser device 609 can be fabricated, either entirely, or in part, in an internal layer of the sub-assembly 605.

Electrical connectivity between the first laser device 608 and the pin 132 of the TO-can package 130 can be provided, for example, via a bonding pad 607, a bonding wire 651, a bonding pad 652, an electrical component 653, another bonding pad 654, and a bonding wire 656. In this exemplary embodiment, the bonding pad 607 is a part of the sub-assembly 605 while the bonding pad 652, the electrical component 653, and the bonding pad 654 are parts of the planar lightwave circuit 631. A similar arrangement can be used to provide electrical connectivity between the second laser device 609 and the pin 136 of the TO-can package 130 via a bonding pad 611 of the sub-assembly 605.

The sub-assembly 605 further includes an optoelectronic element 606 that can be installed or fabricated as a part of the third leg 623. The optoelectronic element 606 represents any of a number of devices that can be used for various purposes.

In a first example implementation, the optoelectronic element 606 is an optical monitoring element that includes an optical coupler (not shown) and an optical-to-electrical converter (not shown). The optical coupler provides for coupling into the optical-to-electrical converter, a portion of light propagating through the third leg 623. The optical-to-electrical converter generates an electrical signal that is coupled to the pin 134 via a bonding pad 612, a bonding wire 624, another bonding pad 626, and a bonding wire 627. In this exemplary embodiment, the bonding pad 612 is a part of the sub-assembly 605 while the bonding pad 626 is a part of the planar lightwave circuit 631.

In a second example implementation, the optoelectronic element 606 is a modulator device that can be introduced into the third leg 623 for modulating light of a single desired wavelength. The light propagating through the third leg 623 can be configured to be light of the single desired wavelength in various ways. For example, a control signal can be applied to the first laser device 608 via pin 132 of the TO-can package 130 for turning off the first laser device 608, or applied to the second laser device 609 via pin 136 of the TO-can package 130 for turning off the second laser device 609. Another bonding pad (not shown) can be used to provide a data input signal to the modulator device when modulating the light of the single desired wavelength that is propagating through the third leg 623 and out of the sub-assembly 605 through the focusing lens 635. Yet another bonding pad (not shown) can be used to provide a control signal can be used to disable the modulator device and permit wavelength multiplexed light to propagate through the third leg 623 without modulation.

Drawing attention back to the electrical component 653, in one example implementation, the electrical component 653 is a laser driver device that can be used to provide one or more signals to the first laser device 608. A few example of such signals include a bias control signal, an on/off signal, and a modulating signal. The modulating signal can be used to modulate an optical signal that is generated by the first laser device 608. When the electrical component 653 is used to provide a modulating signal, the optoelectronic element 606 can be configured as an optical monitoring element rather than as a modulator device. The electrical component 659 can also be a laser driver device that is used to provide one or more signals to the second laser device 609 in a manner similar to that described above with respect to the electrical component 653.

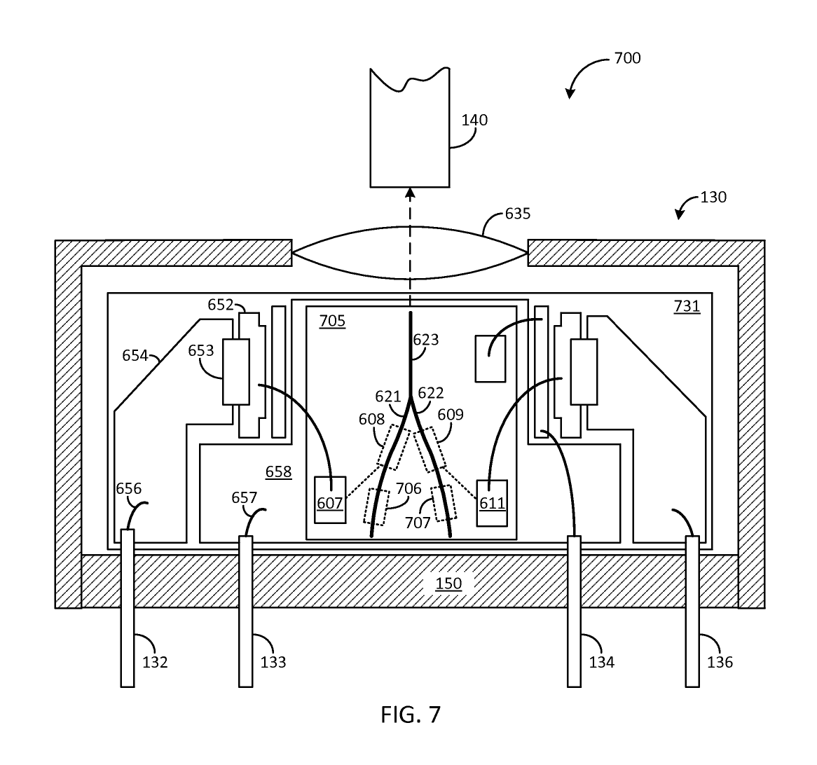

FIG. 7 shows a sixth exemplary embodiment of light emitting device 700 in the form of the TO-can package 130 housing a planar lightwave circuit 731 that includes a fourth set of optoelectronic devices mounted on a sub-assembly 705. In contrast to the sub-assembly 605 described above, in the sub-assembly 705 the first optoelectronic element 606 is omitted and at least two additional devices provided. Of these two additional devices, a first optical monitoring element 706 is arranged in the first leg 621 of the Y-shaped optical waveguide circuit. The first optical monitoring element 706 receives light emitted from a rear facet of the first laser device 608 and converts the monitored light into a first electrical signal that is coupled to a pin of the TO-can package 130 via bonding pads and wires in a manner similar to that described above with respect to the light emitting device 600. The first electrical signal is indicative of an amount of light propagating through the first leg 621 towards the third leg 623 of the Y-shaped optical waveguide circuit.

A second optical monitoring element 707 is arranged in the second leg 622 of the Y-shaped optical waveguide circuit. The second optical monitoring element 707 receives light emitted from a rear facet of the second laser device 609 and converts the monitored light into a second electrical signal that is coupled to another pin of the TO-can package 130 via bonding pads and wires in a manner similar to that described above with respect to the light emitting device 600. The second electrical signal is indicative of an amount of light propagating through the second leg 622 towards the third leg 623 of the Y-shaped optical waveguide circuit.

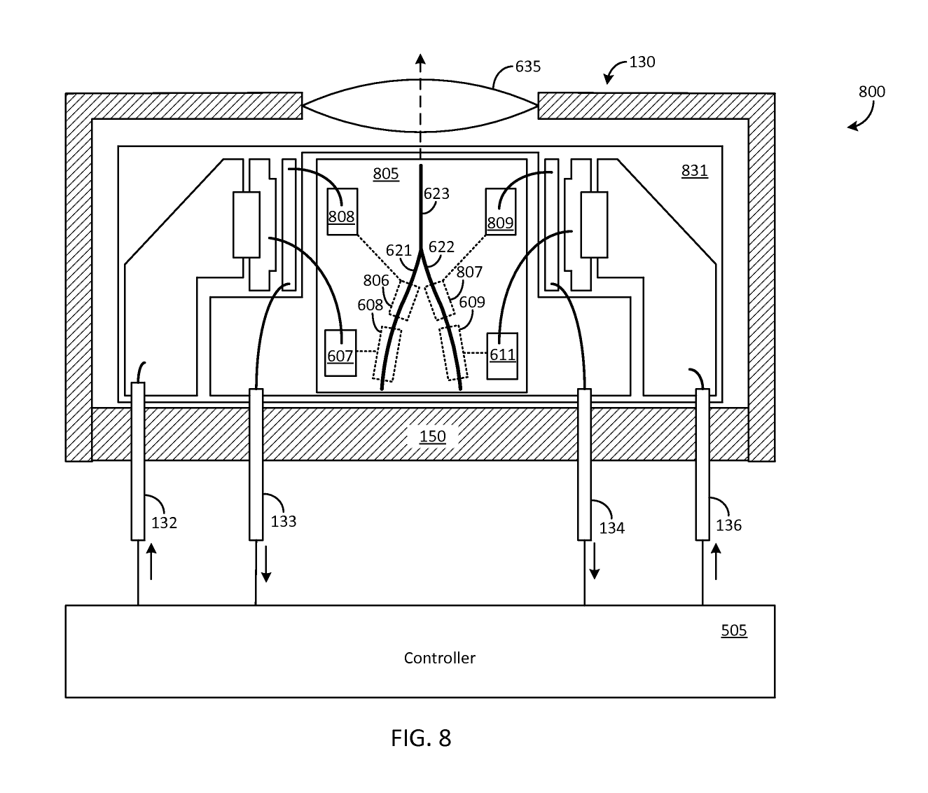

FIG. 8 shows an exemplary optical system 800 that includes the controller 505 communicatively coupled to a light emitting device 800. Some particulars of the controller 505 have been provided above with respect to the exemplary embodiment shown in FIG. 5 and will not be repeated here in the interest of brevity. As for the light emitting device 800, a first optical monitoring element 806 is arranged in the first leg 621 of the Y-shaped optical waveguide circuit. The first optical monitoring element 806 receives light emitted from a front facet of the first laser device 608 and converts the monitored light into a first electrical signal that is coupled to the pin 133 of the TO-can package 130 via a bonding pad 808 on the sub-assembly 805. The first electrical signal is indicative of an amount of light propagating through the first leg 621 towards the third leg 623 of the Y-shaped optical waveguide circuit.

A second optical monitoring element 807 is arranged in the second leg 622 of the Y-shaped optical waveguide circuit. The second optical monitoring element 807 receives light emitted from a front facet of the second laser device 609 and converts the monitored light into a second electrical signal that is coupled to the pin 134 of the TO-can package 130 via a bonding pad 809 on the sub-assembly 805. The second electrical signal is indicative of an amount of light propagating through the second leg 622 towards the third leg 623 of the sub-assembly 705.

The controller 505 uses one or both of the first electrical signal and the second electrical signal to generate one or more control signals and provide these control signals to the first laser 608 and/or the second laser 609 via the pin 132 and the pin 136 respectively. The manner in which the controls signals are generated and applied is similar to that described above with respect to the exemplary embodiment shown in FIG. 5, and will not be repeated here in the interest of brevity.

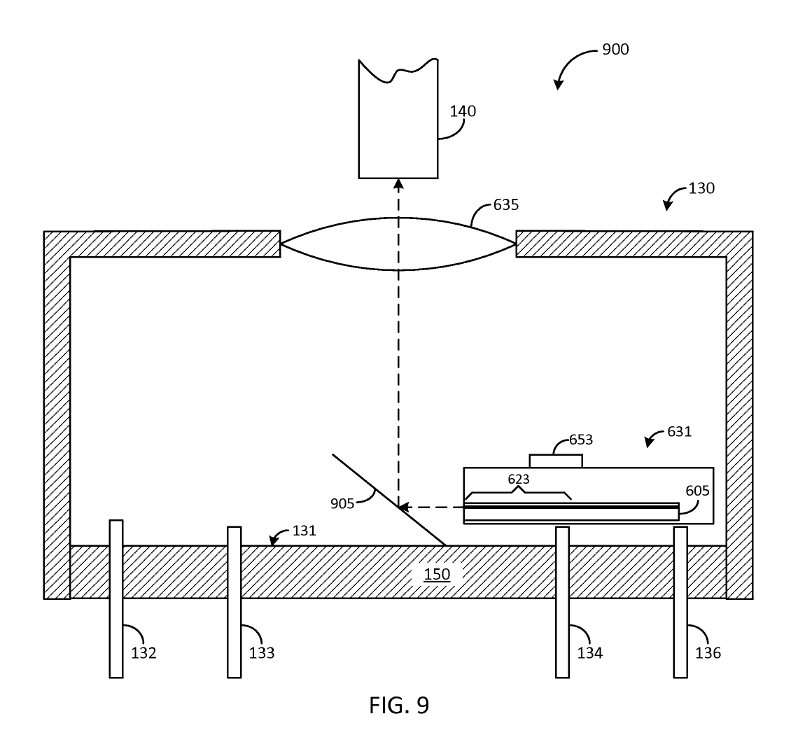

FIG. 9 shows a seventh exemplary embodiment of a light emitting device 900 in the form of a TO-can package 130 housing the planar lightwave circuit 631 in an alternative mounting arrangement to that shown in FIG. 6. Specifically, in this exemplary embodiment, the planar lightwave circuit 631 is mounted directly on the substrate (or on a mounting platform that is mounted on the substrate) with a major surface of the planar lightwave circuit 631 oriented parallel to the top major surface 131 of the substrate 150.

Light emitted out of the third leg 623 of the Y-configuration of three optical waveguides (described above) is directed towards a light directing element 905, which can be a mirror in one example implementation. The light directing element 905 reflects the light received from the third leg 623 (orthogonally, for example) towards the optical fiber 140 via the focusing lens 635. Additional optical elements, such as for example, a collimating lens, can be inserted between the planar lightwave circuit 631 and the light directing element 905.

The planar lightwave circuit 631 can include the electrical component 653 configured as a laser driver device. In an alternative configuration, the electrical component 653 can be an element other than a laser driver, and the laser driver functionality can be provided by using another element (not shown) that is co-located with the planar lightwave circuit 631 on the top major surface 131 of the substrate 150. This other element can be interconnected with the planar lightwave circuit 631 either via metal tracks embedded in the substrate 150, or via jumper wires (not shown).

In summary, it should be noted that the invention has been described with reference to a few illustrative embodiments for the purpose of demonstrating the principles and concepts of the invention. It will be understood by persons of skill in the art, in view of the description provided herein, that the invention is not limited to these illustrative embodiments. Persons of skill in the art will understand that many such variations can be made to the illustrative embodiments without deviating from the scope of the invention.

What is claimed is:

1. A light emitting device comprising:
an optical window that constitutes a light emitting surface of a TO-can package;
a substrate located inside the TO-can package; and
a sub-assembly mounted on the substrate such that a major surface of the sub-assembly is oriented orthogonal to a major surface of the substrate, the sub-assembly comprising:
a first light emitter; and
a first light directing element arranged at a first fixed distance from the first light emitter prior to mounting of the sub-assembly on the substrate, the first fixed distance determined, at least in part, on a first mounted distance formed between the first light directing element and the optical window when the sub-assembly is mounted on the substrate.

2. The device of claim 1, wherein the first light emitter is a laser mounted on the major surface of the sub-assembly, wherein the first light directing element is a primary focusing lens, and wherein the optical window is one of a pane of glass or a secondary focusing lens.

3. The device of claim 2, wherein a light propagating path provided by the first light directing element is substantially aligned with an optical center of the one of the pane of glass or the secondary focusing lens.

4. The device of claim 1, wherein the sub-assembly is a planar lightwave circuit, the first light emitter is an intrinsic component of the planar lightwave circuit, and the optical window is one of a pane of glass or a focusing lens.

5. The device of claim 4, wherein the first light emitter is a laser that is fabricated, at least in part, in an internal layer of the planar lightwave circuit, and wherein the first light directing element is an optical waveguide that is substantially aligned with an optical center of the one of the pane of glass or the focusing lens.

6. The device of claim 1, wherein the sub-assembly further comprises:
a second light emitter; and
a second light directing element arranged at a second fixed distance from the second light emitter prior to mounting of the sub-assembly on the substrate, the second fixed distance determined, at least in part, on a second mounted distance formed between the second light directing element and the optical window when the sub-assembly is mounted on the substrate.

7. The device of claim 6, wherein the first light emitter and the first light directing element are optically aligned with each other along a first vertical axis, the first vertical axis substantially parallel to a second vertical axis along which the second light emitter and the second light directing element are optically aligned with each other.

8. The device of claim 7, wherein each of the first light directing element and the second light directing element is configured to provide a light propagating axis that is angled with respect to the optical window.

9. A light emitting device comprising:
an optical window that constitutes a light emitting surface of a TO-can package;
a substrate located inside the TO-can package;
a first light emitter mounted on the substrate such that a first light emitting axis of the first light emitter is substantially parallel to a major surface the substrate;
a second light emitter mounted on the substrate such that a second light emitting axis of the second light emitter is substantially parallel to the major surface of the substrate; and
a light directing element mounted on the substrate, the light directing element configured to redirect towards the optical window, each of a first beam of light received from the first light emitter along the first light emitting axis and a second beam of light received from the second light emitter along the second light emitting axis.

10. The device of claim 9, wherein the light directing element comprises:
a first reflecting surface angularly inclined at 45 degrees with respect to the major surface of the substrate, the first reflecting surface providing to the first beam of light received from the first light emitter, a first substantially orthogonal redirection; and
a second reflecting surface angularly inclined at 45 degrees with respect to the major surface of the substrate, the second reflecting surface providing to the second beam of light received from the second light emitter, a second substantially orthogonal redirection.

11. The device of claim 9, wherein the light directing element comprises:
a first reflecting surface angularly inclined at less than 45 degrees with respect to the major surface of the substrate, the first reflecting surface providing to the first beam of light received from the first light emitter, a first redirection that is greater than 90 degrees; and
a second reflecting surface angularly inclined at less than 45 degrees with respect to the major surface of the substrate, the second reflecting surface providing to the second beam of light received from the second light emitter, a second redirection that is greater than 90 degrees.

12. The device of claim 11, wherein the first reflecting surface is located on an obverse side of the light directing element and the second reflecting surface located on a reverse side of the light directing element.

13. A light emitting device comprising:
an optical window that constitutes a light emitting surface of a TO-can package;
a substrate located inside the TO-can package; and
a planar lightwave circuit mounted on the substrate, the planar lightwave circuit comprising:
an optical waveguide combiner comprising a first leg, a second leg, and a third leg, the third leg arranged to combine light received from the first leg and the second leg;
a first light emitter configured to propagate into the first leg of the optical waveguide combiner, light at a first wavelength;
a second light emitter configured to propagate into the second leg of the optical waveguide combiner, light at a second wavelength; and
at least one of a first optical monitoring element, a second optical monitoring element, or a third optical monitoring element, wherein the first optical monitoring element is optically coupled to the first leg for generating a first electrical signal indicative of a first amount of light propagating through the first leg at the first wavelength, the second optical monitoring element is optically coupled to the second leg for generating a second electrical signal indicative of a second amount of light propagating through the second leg at the second wavelength, and the third optical monitoring element optically coupled to the third leg for generating a third electrical signal indicative of a third amount of light propagating through the third leg.

14. The device of claim 13, wherein at least one of the first light emitter, the second light emitter, or the optical monitor circuit is fabricated, at least in part, in an internal layer of the planar lightwave circuit.

15. The device of claim 13, wherein the planar lightwave circuit is mounted on the substrate such that a major surface of the planar lightwave circuit is oriented orthogonal to a major surface of the substrate

16. The device of claim 15, wherein the optical window includes a lens, and the third leg of the optical monitor circuit is substantially aligned with a principal axis of the lens.

17. The device of claim 16, further comprising a light directing element configured to direct to the lens, light received from the third leg of the optical waveguide combiner.

18. An optical system comprising:
a TO-can package comprising a first lead, a second lead, a third lead, a fourth lead, and a light emitting circuit housed inside the TO-can package, the light emitting circuit comprising:
a first light emitting device configured to emit light at a first wavelength, the first light emitting device having a first control input signal terminal that is coupled to the first lead of the TO-can package;
a second light emitting device configured to emit light at a second wavelength, the second light emitting device having a second control input signal terminal that is coupled to the second lead of the TO-can package;
a first optical monitor circuit operable to generate a first monitor output signal indicative of a first amount of light emitted by the first light emitting device at the first wavelength, the first monitor output signal provided to a first monitor output signal terminal that is coupled to the third lead of the TO-can package; and
a second optical monitor circuit operable to generate a second monitor output signal indicative of a second amount of light emitted by the second light emitting device at the second wavelength, the second monitor output signal provided on a second monitor output signal terminal that is coupled to the fourth lead of the TO-can package; and
a controller configured to receive at least one of the first monitor output signal via the third lead of the TO-can package or the second monitor output signal via the fourth lead of the TO-can package, and derive therefrom, at least one of a first control signal or a second control signal, the controller further configured to provide at least one of the first control signal or the second control signal to a respective one of the first light emitting device or the second light emitting device via a respective one of the first lead or the second lead of the TO-can package.

19. The optical system of claim 18, wherein the at least one of the first control signal or the second control signal is operative to modify at least one characteristic of the light emitted by the first light emitting device at the first wavelength or light emitted by the second light emitting device at the second wavelength.

20. The optical system of claim 18, wherein the at least one of the first control signal or the second control signal is operative to disable emission of light by at least one of the first light emitting device or the second light emitting device.
